(19) United States
(12) Patent Application Publication
(10) Pub. No.: US 2023/0360906 A1
(43) Pub. Date: Nov. 9, 2023

(54) SILICON-AND-CARBON-CONTAINING MATERIALS WITH LOW DIELECTRIC CONSTANTS

(71) Applicant: Applied Materials, Inc., Santa Clara, CA (US)

(72) Inventors: Zeqing Shen, San Jose, CA (US); Susmit Singha Roy, Sunnyvale, CA (US); Abhijit Basu Mallick, Fremont, CA (US)

(73) Assignee: Applied Materials, Inc., Santa Clara, CA (US)

(21) Appl. No.: 17/737,328

(22) Filed: May 5, 2022

(51) Int. Cl. H01L 21/02; H01L 21/311

(52) U.S. Cl. CPC H01L 21/02211; H01L 21/02532; H01L 21/02123; H01L 21/0234; H01L 21/31111; H01L 29/42392

(57) ABSTRACT

Exemplary methods of semiconductor processing may include providing a silicon-containing precursor and a carbon-containing precursor to a processing region of a semiconductor processing chamber. The carbon-containing precursor may be characterized by a carbon-carbon double bond or a carbon-carbon triple bond. A substrate may be disposed within the processing region of the semiconductor processing chamber. The methods may include providing an oxygen-containing precursor to the processing region of the semiconductor processing chamber. The methods may include thermally reacting the silicon-containing precursor, the carbon-containing precursor, and the oxygen-containing precursor at a temperature less than or about 700° C. The methods may include forming a silicon-and-carbon-containing layer on the substrate.

### TECHNICAL FIELD

The present technology relates to methods and components for semiconductor processing. More specifically, the present technology relates to systems and methods for producing silicon-and-carbon-containing films for semiconductor structures.

### BACKGROUND

Integrated circuits are made possible by processes which produce intricately patterned material layers on substrate surfaces. Producing patterned material on a substrate requires controlled methods for forming and removing material. As device sizes continue to reduce, aspect ratios of structures may grow, and maintaining dimensions of these structures during processing operations may be challenged. Developing dielectric materials that may have sufficient conformality across features may be a challenge. Additionally, as the number of material layers being patterned during processing is expanding, producing materials that may have improved removal selectivity to other exposed materials is becoming a greater challenge, along with maintaining material properties.

Thus, there is a need for improved systems and methods that can be used to produce high quality devices and structures. These and other needs are addressed by the present technology.

### SUMMARY

Exemplary methods of semiconductor processing may include providing a silicon-containing precursor and a carbon-containing precursor to a processing region of a semiconductor processing chamber. The carbon-containing precursor may be characterized by a carbon-carbon double bond or a carbon-carbon triple bond. A substrate may be disposed within the processing region of the semiconductor processing chamber. The methods may include providing an oxygen-containing precursor to the processing region of the semiconductor processing chamber. The methods may include thermally reacting the silicon-containing precursor, the carbon-containing precursor, and the oxygen-containing precursor at a temperature less than or about 700° C. The methods may include forming a silicon-and-carbon-containing layer on the substrate.

In some embodiments, the oxygen-containing precursor may be or include nitrous oxide. Thermally reacting the silicon-containing precursor, the carbon-containing precursor, and the oxygen-containing precursor may be performed at a temperature less than or about 575° C. A pressure within the semiconductor processing chamber may be maintained at greater than or about 3 Torr while forming the silicon-and-carbon-containing layer. The processing region of the semiconductor processing chamber may be maintained plasma-free while forming the silicon-and-carbon-containing layer on the substrate. The carbon-containing precursor may be provided at a flow rate ratio to the silicon-containing precursor of greater than or about 4:1. The substrate may be characterized by one or more features. The silicon-and-carbon-containing layer may be formed about the one or more features with a conformality of greater than or about 80%. The silicon-and-carbon-containing layer may be characterized by a carbon concentration of less than or about 30 at. %. The methods may include cycling delivery of the oxygen-containing precursor while maintaining delivery of the silicon-containing precursor and the carbon-containing precursor. Periods of time of providing the oxygen-containing precursor may be between about 0.5 s and about 10 s. The silicon-and-carbon-containing layer may be formed at least partially around one or more alternating stacks of silicon and silicon germanium.

Some embodiments of the present technology encompass semiconductor processing methods. The methods may include providing a silicon-containing precursor and a carbon-containing precursor to a processing region of a semiconductor processing chamber. The carbon-containing precursor may be provided at a flow rate ratio to the silicon-containing precursor of greater than or about 4:1. A substrate may be disposed within the processing region of the semiconductor processing chamber. The methods may include providing an oxygen-containing precursor to the processing region of the semiconductor processing chamber. The methods may include thermally reacting the silicon-containing precursor, the carbon-containing precursor, and the oxygen-containing precursor at a temperature less than or about 650° C. The methods may include forming a silicon-and-carbon-containing layer on the substrate.

In some embodiments, the oxygen-containing precursor may be or include nitrous oxide. The processing region of the semiconductor processing chamber may be maintained plasma-free during the semiconductor processing method. The methods may include cycling delivery of the oxygen-containing precursor while maintaining delivery of the silicon-containing precursor and the carbon-containing precursor. Periods of time of providing the oxygen-containing precursor are between about 0.5 s and about 10 s.

Some embodiments of the present technology encompass semiconductor processing methods. The methods may include providing a silicon-containing precursor and a carbon-containing precursor to a processing region of a semiconductor processing chamber. The silicon-containing precursor may be or include disilane. The carbon-containing precursor may be characterized by a carbon-carbon double bond or a carbon-carbon triple bond. A substrate may be disposed within the processing region of the semiconductor processing chamber. One or more alternating stacks of silicon and silicon germanium may be disposed on the substrate. The methods may include providing an oxygen-containing precursor to the processing region of the semiconductor processing chamber. The oxygen-containing precursor may be or include nitrous oxide. The oxygen-containing precursor may be provided discontinuously. The methods may include thermally reacting the silicon-containing precursor, the carbon-containing precursor, and the oxygen-containing precursor at a temperature less than or about 600° C. The methods may include forming a silicon-and-carbon-containing layer on the substrate. The silicon-and-carbon-containing layer may be formed at least partially around the one or more alternating stacks of silicon and silicon germanium.

In some embodiments, the processing region of the semiconductor processing chamber may be maintained plasma-free during the semiconductor processing method. The silicon-and-carbon-containing layer may be formed about the one or more features with a conformality of greater than or about 85%. The silicon-and-carbon-containing layer may be characterized by a carbon concentration of less than or about 30 at. %. The methods may include exposing the silicon-and-carbon-containing layer to an oxygen-containing plasma, a hydrogen-containing plasma, or a wet etch process. The silicon-and-carbon-containing layer may be maintained at least 50% of the thickness.

Such technology may provide numerous benefits over conventional systems and techniques. For example, embodiments of the present technology may produce silicon-and-carbon-containing materials characterized by an increased carbon concentration compared to conventional techniques. Additionally, the present technology may produce carbon-containing films with tunable film characteristics having increased mechanical and electrical properties. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

FIGS. 3A-3C show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size in order to scale devices. As structures are brought closer together within a device, maintaining uniformity across structures may be more difficult. Further, dielectric materials may play an important role in limiting crosstalk and other electrical issues. Current materials may be incapable of sufficiently reduced dielectric constants without sacrificing material or electrical properties of the film. For example, by adjusting film properties to lower dielectric constant with some materials, the leakage characteristics of the material may increase and the breakdown properties of the film may reduce, which may lead to device failure. Additionally, for these films to be incorporated in semiconductor integration, processing may include a back-end-of-line anneal process that may expose structures to temperatures exceeding 600° C. or more. Many films may be impacted by this anneal, which can cause outgassing that may lead to increased dielectric constant.

The present technology overcomes these issues by performing a thermally-based material deposition, which may not utilize plasma generation during the deposition process. By performing a thermal reaction between specific silicon-containing precursors, carbon-containing precursors, and/or oxygen-containing precursors, the present technology may allow lower-temperature chemical-vapor deposition to be performed, which may provide conformal growth on any number of semiconductor structures. The process performed may allow increased tuning of the films being produced, affording films characterized by a variety of material properties for different applications.

Although the remaining disclosure will routinely identify specific deposition processes utilizing the disclosed technology, and will describe one type of semiconductor processing chamber, it will be readily understood that the processes described may be performed in any number of semiconductor processing chambers, as well as for any number of processing operations in which films as described may be incorporated. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

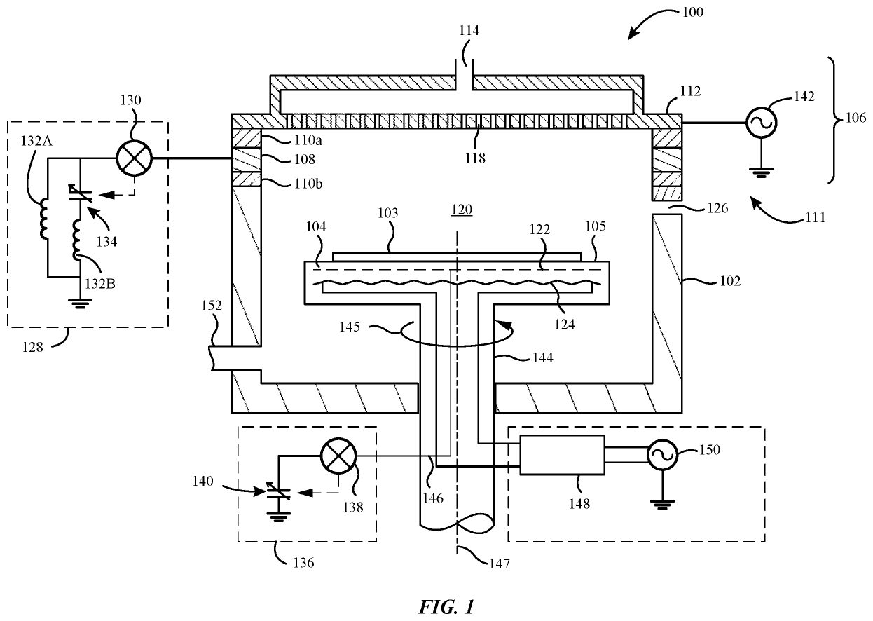

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

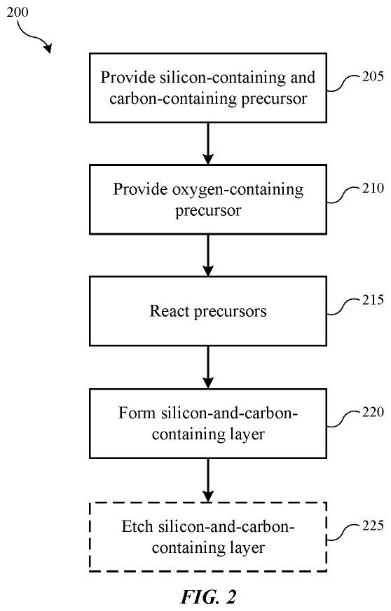

As discussed previously, although a plasma-processing chamber may be used for one or more aspects of film processing according to the present technology, in some embodiments, forming silicon and carbon films may not utilize a plasma-enhanced process. Utilizing plasma may limit conformality of the film produced by further releasing carbon from precursors, and which may limit carbon incorporation in the films produced by allowing the carbon to recombine with other radical species and flow from the chamber. The present technology may at least form the film without plasma generation in some embodiments. FIG. 2 shows exemplary operations in a processing method 200 according to some embodiments of the present technology. The method may be performed in a variety of processing chambers, including processing chamber 100 described above, as well as any other chambers including non-plasma chambers, in which the operations may be performed. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may include a processing method that may include a number of operations for developing a silicon-and-carbon-containing film, which may include a tunable ratio of carbon within the film. As will be explained further below, modifying the ratios of silicon and carbon, as well as how the materials integrate within the film, may provide a number of properties to facilitate device processing for a number of structures.

At operation 205, the method may include providing a silicon-containing precursor and a carbon-containing precursor to the processing region of a semiconductor processing chamber where a substrate may be housed. At operation 210, which may occur simultaneously with operation 205, as well as prior to or subsequent operation 205, an oxygen-containing precursor may be provided to the processing region of the semiconductor processing chamber. At operation 215, the silicon-containing precursor, the carbon-containing precursor, and the oxygen-containing precursor may be thermally reacted within the processing region of the semiconductor processing chamber, which may form a silicon-and-carbon-containing layer on the substrate at operation 220.

Because of the reaction being performed in some embodiments, the semiconductor processing chamber, the pedestal, or the substrate 305 may be maintained at a temperature greater than or about 250° C., and in some embodiments may be maintained at a temperature that is greater than or about 300° C., greater than or about 320° C., greater than or about 340° C., greater than or about 360° C., greater than or about 380° C., greater than or about 400° C., greater than or about 420° C., greater than or about 440° C., greater than or about 460° C., greater than or about 480° C., greater than or about 500° C., greater than or about 520° C., greater than or about 540° C., or more. Similarly, in some embodiments, the semiconductor processing chamber, the pedestal, or the substrate 305 may be maintained at a temperature less than or about 700° C., and in some embodiments may be maintained at a temperature that is less than or about 680° C., less than or about 660° C., less than or about 640° C., less than or about 620° C., less than or about 600° C., less than or about 580° C., less than or about 575° C., less than or about 560° C., less than or about 540° C., or less.

The semiconductor processing chamber may be maintained at a pressure greater than or about 3 Torr, and in some embodiments may be maintained at a pressure that is greater than or about 5 Torr, greater than or about 10 Torr, greater than or about 15 Torr, greater than or about 25 Torr, greater than or about 50 Torr, greater than or about 75 Torr, greater than or about 100 Torr, greater than or about 125 Torr, greater than or about 150 Torr, greater than or about 175 Torr, greater than or about 200 Torr, greater than or about 225 Torr, greater than or about 250 Torr, greater than or about 275 Torr, greater than or about 300 Torr, or more.

As previously discussed, some or all of the formation operations may be performed while the substrate processing region is maintained plasma-free. By performing a thermal chemical-vapor deposition, a more conformal material formation may be produced, as well as a material characterized by increased carbon incorporation. Non-limiting examples of silicon-containing precursors that may be used during processing according to some embodiments of the present technology may include silane, disilane, silicon tetrafluoride, silicon tetrachloride, dichlorosilane, tetraethyl orthosilicate, as well as any other silicon-containing precursors that may be used in silicon-containing film formation. The carbon-containing precursor may be or include any number of carbon-containing precursors. For example, the carbon-containing precursor may be or include any hydrocarbon, or any material including or consisting of carbon and hydrogen. In some embodiments, to facilitate the reaction between the carbon precursor and the silicon or oxygen precursor, the carbon-containing precursor may be characterized by one or more carbon-carbon double bonds and/or one or more carbon-carbon triple bonds. Accordingly, in some embodiments the carbon-containing precursor may be or include an alkene or an alkyne, such as acetylene, ethylene, propene, or any other carbon-containing material. The precursor may include carbon-and-hydrogen-containing precursors, which may include any amount of carbon and hydrogen bonding, along with any other element bonding, although in some embodiments the carbon-containing precursor may consist of carbon-to-carbon and carbon-to-hydrogen bonding. Oxygen-containing precursors used in any operation as described throughout the present technology may include diatomic oxygen, nitrous oxide, nitrogen dioxide, ozone, as well as any other oxygen-containing precursors that may be used in silicon oxide film formation, although in some embodiments the oxygen-containing precursor may not include a hydroxyl moiety. Using oxygen-containing precursors that may include reduced oxygen incorporation, such as precursors including a single bonded oxygen, including nitrous oxide as one non-limiting example, may result in a more controlled reaction rate and oxygen incorporation, which may facilitate additional tuning of carbon incorporation within the film to produce film characteristics for a variety of applications.

A number of factors may impact the silicon, oxygen, and carbon concentration within the films. For example, in some embodiments, the produced film may be limited to or consist essentially of silicon, oxygen, carbon, and hydrogen, along with any trace materials, which may account for contaminants, for example. In some embodiments, the silicon concentration within the film may be maintained at less than or about 50 at. %, which may help limit leakage current of the produced film, as a more silicon-rich film may be characterized by higher leakage. Accordingly, in some embodiments the produced material before or after an anneal may be characterized by a silicon concentration of less than or about 48%, and may be maintained at less than or about 45 at. %, less than or about 40 at. %, less than or about 38 at. %, less than or about 36 at. %, less than or about 34 at. %, less than or about 32 at. %, less than or about 30 at. %, less than or about 28 at. %, less than or about 26 at. %, less than or about 24 at. %, less than or about 22 at. %, less than or about 20 at. %, or less.

The oxygen concentration within the film may be maintained below or about 60%, which may indicate the amount silicon and carbon that remain in the film after an anneal, where a lower oxygen content may indicate more silicon and carbon may be retained. Accordingly, in some embodiments the produced material before or after an anneal as discussed below may be characterized by an oxygen concentration of greater than or about 5 at. %, and may be greater than or about 10 at. %, greater than or about 15 at. %, greater than or about 20 at. %, greater than or about 25 at. %, greater than or about 30 at. %, greater than or about 35 at. %, greater than or about 40 at. %, greater than or about 45 at. %, greater than or about 50 at. %, or more.

The present technology may be able to tune a carbon incorporation within the film based on flow rates as will be discussed below. In embodiments of the present technology, produced films may be characterized by a carbon concentration within the produced material before or after an anneal as discussed below of less than or about 30 at. %, and may be maintained at less than or about 28 at. %, less than or about 26 at. %, less than or about 24 at. %, less than or about 22 at. %, less than or about 20 at. %, less than or about 18 at. %, less than or about 16 at. %, less than or about 14 at. %, less than or about 12 at. %, less than or about 10 at. %, or less. For example, the thermal reaction may proceed based on dissociation of the silicon-containing precursor, the radical effluents of which may facilitate dissociation of the carbon-containing precursor. However, formation of silicon-silicon bonds may compete with formation of silicon-carbon bonds, and thus the amount of carbon incorporation may be limited to a threshold of about 30 at. % or less depending on the carbon-containing precursor. Additionally, carbon-containing precursors including a carbon-carbon triple bond may be more readily dissociated than carbon-containing precursors only including one or more carbon-carbon double bonds. Accordingly, increasing a flow rate of a carbon-containing precursor including one or more double bonds may be limited to producing a carbon incorporation of less than or about 25 at. %, while increasing a flow rate of a carbon-containing precursor including one or more triple bonds may afford carbon incorporation up to a threshold of less than or about 30 at. %.

However, the present technology may further increase the carbon concentration in produced films by providing the oxygen-containing precursor discontinuously. That is, in some embodiments, the method 200 may include cycling delivery of the oxygen-containing precursor while maintaining delivery of the silicon-containing precursor and the carbon-containing precursor. This may increase the amount of carbon radical species available for the deposition relative to the oxygen radical species, and which may allow the carbon concentration to be higher compared to conventional technologies. Accordingly, in some embodiments, the oxygen-containing precursor may be cycled on and off for equal or unequal periods of time. The periods of time of cycling the oxygen-containing precursor on and off may be greater than or about 0.5 s, and may be greater than or about 1 s, greater than or about 3 s, greater than or about 5 s, greater than or about 7, greater than or about 9 s, or more. In some embodiments, periods of time of providing the oxygen-containing precursor may be between about 0.5 s and about 10 s.

Hydrogen incorporation in the film may impact one or more material properties, as well as the quality of the film produced. Although the carbon-containing precursor and/or the silicon-containing precursor may include hydrogen, in some embodiments no additional source of hydrogen may be provided. Although inert precursors or carrier gases may be provided with the silicon-containing precursor and the carbon-containing precursor, no other chemically reactive precursors may be delivered with the precursors in some embodiments. By limiting the hydrogen provided to the chamber to hydrogen included in the carbon-containing precursor and the silicon-containing precursor, an atomic ratio of hydrogen within the produced film may be lower than if hydrogen gas were additionally provided.

To produce films characterized by lower dielectric constant while maintaining sufficient leakage and breakdown performance, the present technology may deliver the precursors to control atomic incorporation, and facilitate bonding between silicon and carbon, which may increase film quality and performance. In many processing operations, silicon may readily bond to itself and form within a film. At higher flow rates, increased carbon-hydrogen bonding may remain, or the carbon may bond around oxygen, which may then be more prone to outgassing from the film. Accordingly, flow rates of the silicon-containing precursor and the carbon-containing precursor may be maintained low to ensure increased bonding may occur between the carbon and silicon. Accordingly, flow rates of the silicon-containing precursor may be maintained low to ensure increased incorporation of carbon materials. For example, in some embodiments, a flow rate of the silicon-containing precursor may be maintained at less than or about 100 sccm, and may be maintained at less than or about less than or about 75 sccm, less than or about 50 sccm, less than or about 25 sccm, less than or about 20 sccm, less than or about 15 sccm, less than or about 10 sccm, less than or about 9 sccm, less than or about 8 sccm, less than or about 7 sccm, less than or about 6 sccm, less than or about 5 sccm, or less. By maintaining the silicon-containing precursor flow rate sufficiently low, silicon incorporation may be controlled while allowing the silicon radicals to facilitate carbon material dissociation.

By maintaining the carbon-containing precursor flow rate sufficiently low, improved carbon-to-silicon bonding may occur, which may limit shrinkage and outgassing during subsequent anneal processing. For example, as the carbon-containing precursor flow rate increases above 50 sccm or more, increased dangling bonds may be incorporated within the film, and annealing the film may further reduce carbon and hydrogen incorporation, which may push dielectric constant higher. Accordingly, by maintaining lower flow rates of the carbon-containing precursor, dielectric constant may be further reduced. This may also help maintain a higher breakdown voltage of the film produced. Hence, in some embodiments of the present technology the flow rate of the carbon-containing precursor may be maintained at less than or about 100 sccm, and may be maintained at less than or about 90 sccm, less than or about 80 sccm, less than or about 70 sccm, less than or about 60 sccm, less than or about 50 sccm, less than or about 40 sccm, less than or about 30 sccm, greater than or about 25 sccm, less than or about 24 sccm, less than or about 23 sccm, less than or about 22 sccm, less than or about 21 sccm, less than or about 20 sccm, less than or about 19 sccm, less than or about 18 sccm, or less.

Providing the precursors at certain ratios to one another may also facilitate control of the film formation to produce the properties and characteristics previously described. For example, in some embodiments the flow rate of the carbon-containing precursor may be maintained higher than the silicon-containing precursor, which may help increase carbon incorporation within the film. Hence, in some embodiments the flow rate ratio of the carbon-containing precursor to the silicon-containing precursor may be maintained at greater than or about 1:1, and may be maintained at greater than or about 2:1, greater than or about 4:1, greater than or about 5:1, greater than or about 6:1, or higher.

Although the produced materials may be impacted by an anneal, the present technology may produce films characterized by lower dielectric constant before or subsequent an anneal, and may produce materials characterized by a dielectric constant of less than or about 4.20, and may be characterized by a dielectric constant of less than or about 4.15, less than or about 4.10, less than or about 4.05, less than or about 4.00, less than or about 3.95, less than or about 3.90, less than or about 3.85, less than or about 3.80, or lower. Additionally, materials produced according to embodiments of the present technology may have the dielectric constant increase after an anneal as noted above by less than or about 1.5, and may have the dielectric constant increase by less than or about 1.4, less than or about 1.3, less than or about 1.2, less than or about 1.1, less than or about 1.0, less than or about 0.9, less than or about 0.8, less than or about 0.7, less than or about 0.6, or the dielectric constant may substantially or essentially remain consistent after an anneal. During an anneal, increased bonding between silicon and carbon in the films may, in some embodiments, increase the dielectric constant. This increase may be resultant of residual hydrogen in the film outgassing and/or excess silicon or carbon in the film bonding during the anneal.

Leakage current and dielectric breakdown may be impacted by the atomic concentrations within the materials produced. However, by producing materials according to embodiments of the present technology, leakage current at 2 MV/cm may be maintained at less than or about 5.0E−8 A/cm², and may be maintained at less than or about 4.0E−8 A/cm², less than or about 3.0E−8 A/cm², less than or about 2.8E−8 A/cm², less than or about 2.6E−8 A/cm², less than or about 2.4E−8 A/cm², less than or about 2.2E−8 A/cm², less than or about 2.0E−8 A/cm², less than or about 1.8E−8 A/cm², less than or about 1.6E−8 A/cm², less than or about 1.4E−8 A/cm², less than or about 1.2E−8 A/cm², less than or about 1.0E−8 A/cm², or less. Additionally, breakdown voltage of the film at 0.001 A/cm² may be maintained at greater than or about 6.0 MV/cm, and may be maintained at greater than or about 6.5 MV/cm, greater than or about 7.0 MV/cm, greater than or about 7.5 MV/cm, greater than or about 8.0 MV/cm, greater than or about 8.5 MV/cm, greater than or about 9.0 MV/cm, greater than or about 9.5 MV/cm, greater than or about 10.0 MV/cm, greater than or about 10.5 MV/cm, greater than or about 11.0 MV/cm, or higher.

Silicon-and-carbon materials produced by the present technology may be used in a number of structures, and may be a mask, liner, or spacer, for example, which may be maintained in a developed structure, and exposed to a number of subsequent processing operations. In some embodiments, the silicon-and-carbon materials may be included as materials used in integration, which may be maintained or removed, after subsequent processing has been performed, which may include an anneal at a downstream process, which may exceed temperatures of 700° C., and may be performed at temperatures of greater than or about 750° C., greater than or about 800° C., greater than or about 850° C., or higher. Because of the improved film bonding and growth produced by some embodiments of the present technology, the low dielectric materials may be less damaged by the anneal process, affording additional integration operations for low dielectric constant materials. For example, during many silicon oxycarbide film formations, the carbon may form about the oxygen, which may increase loss of carbon and hydrogen in an anneal. By performing depositions according to embodiments of the present technology in which improved silicon-carbon bonding may be performed, the carbon may be better retained during an anneal as well as subsequent processing. For example, in many applications where the material may be utilized as a low-k spacer, as will be discussed further below, subsequent processing and layer development may expose the film to photoresist or organic layer ashing, material etching and cleaning, or other processes that may damage a film that is less structurally sound. For example, materials produced by the present technology may be exposed to ashing with oxygen-containing and/or hydrogen-containing materials, as well as etching with halogen-containing materials. By maintaining sufficient oxygen in the structure, the materials may better resist ashing, and by having sufficient carbon incorporation the materials may better resist etch processes.

The silicon, oxygen, and carbon concentration within the films may be tuned depending on desired ash and etch survivability. As previously discussed, the films may be subjected to subsequent processing, including, but not limited to, ash and etch operations at optional operation 225. Films with lower carbon concentrations may be prone to better survivability to ash operations, and films with higher carbon concentrations may be prone to lesser survivability to ash operations. Conversely, films with lower carbon concentrations may be prone to lesser survivability to etch operations, and films with higher carbon concentrations may be prone to better survivability to ash operations. Furthermore, the type of silicon and carbon bonding in the films may also affect survivability. For example, films having Si—C—Si bonds may be the most table for ash operations, which may be due to reduced amounts of hydrogen in the film, as opposed to films having Si—C bonds, Si—CH₃ bonds, or C—C bonds. The different forms of bonding may be manipulated by modifying precursors and flows. For example, too much carbon incorporation in the film, either by carbon-containing precursors or flow of said precursors, may add unstable carbon in the film. Depending on integration operations, it may be desirable to tune the carbon concentration and/or type of bonding in the film depending on ash and etch operations subsequent to depositing the films of the present technology. In embodiments with increased etch operations relative to ash operations, it may be desirable to increase the carbon concentration in the film. Conversely, in embodiments with increased ash operations relative to etch operations, it may be desirable to decrease the carbon concentration in the film.

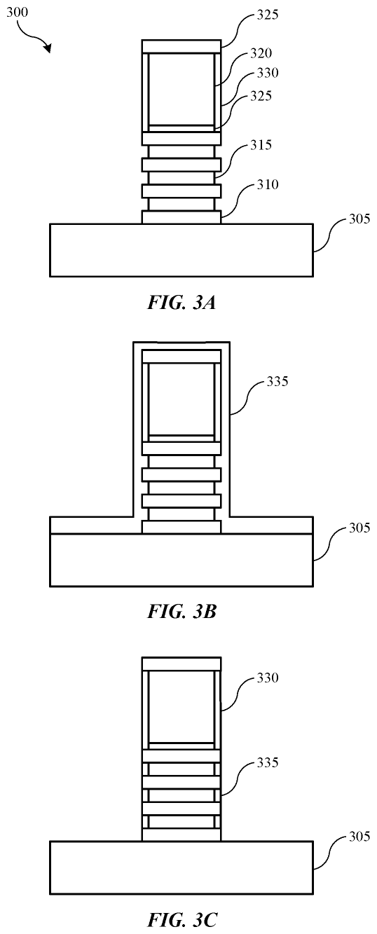

As explained previously, in some embodiments the thermally based material formation may provide more conformal films, which may operate as a liner, spacer, or other material used during semiconductor processing. Although the remaining figures will discuss a gate all around (“GAA”) structure including films produced by the present technology, the present materials may be used in any number of structures. For example, in some embodiments films may be used in memory applications, such as DRAM, and the materials may be incorporated as spacers about the structure, such as for a bitline spacer, as one non-limiting example. FIGS. 3A-3C show exemplary schematic cross-sectional structures in which material layers are included and produced according to some embodiments of the present technology. For example and as illustrated in FIG. 3A, the structure 300 may include substrate 305, which may be any number of materials, such as a base wafer or substrate 305 made of silicon or silicon-containing materials, other substrate 305 materials, as well as one or more materials that may be formed overlying the substrate 305 during semiconductor processing. For example, in some embodiments the substrate 305 may be processed to include one or more materials or structures for semiconductor processing. Substrate 305 may be or include a dielectric material, such as an oxide or nitride of any number of materials. The substrate 305 may be processed to form one or more layers of material on the substrate 305. As illustrated in FIG. 3A, the layers of material may be deposited to begin formation of a GAA transistor structure. In embodiments, the substrate 305 may include one or more features, such as alternating stacks of silicon 310 and silicon germanium 315, although it is to be understood that the materials may be reversed for different regions along a substrate or device structure. The silicon germanium 315 may be recessed inward compared to the silicon 310. In subsequent processing, the silicon 310 may be exposed to form the source and drain regions on opposite sides of the gate. A gate or gate placeholder 320 may be disposed on top of the alternating stacks of silicon 310 and silicon germanium 315. A silicon oxide material 325 may be disposed on both the bottom and top of the gate or gate placeholder 320. A liner material 330 may be disposed on the sides of the gate or gate placeholder 320. As illustrated in FIG. 3B, in some embodiments of the present technology, a silicon-and-carbon-containing layer 335 may be formed over the structure 300, such as around the one or more alternating stacks of silicon 310 and silicon germanium 315. It is to be understood that this example is not intended to be limiting, as the present technology may be utilized in any number of processing operations and that the materials of the structure 300 may be any other materials appreciated by those skilled in the art. Formation of the film may occur based on methods or operations previously described, which may provide a more conformal deposition, and which may advantageously accommodate the gate structure having one or more recessed materials.

Silicon-and-carbon films produced by the present technology may be characterized by coverage fully about the structure as illustrated. For example, a thickness of the film along sidewalls nearer the top of the structure and a thickness of the film along sidewalls nearer the bottom of the structure may be substantially the same, where the film produced is substantially conformal. Accordingly, in some embodiments the film deposited may be characterized by a conformality or a similarity of thickness formed between any two regions including a region across the top of a feature, along a sidewall, and/or at a base between features, as well as anywhere along the film formed, of greater than or about 80%. In some embodiments, the conformality may be greater than or about 85%, greater than or about 90%, greater than or about 92%, greater than or about 94%, greater than or about 96%, greater than or about 98%, or higher. Accordingly, the present technology may produce silicon-and-carbon containing films characterized by a low dielectric constant and an increased carbon incorporation compared to conventionally developed films. Subsequent processing, such as shown in FIG. 3C, may recess the spacer material of silicon-and-carbon-containing layer 335 to the regions recessed along the gate structure. Additional processing may be performed in development of the GAA transistor. This may include a number of processes that may expose the silicon-and-carbon-containing layer 335 to etchant materials, such as may include fluorine or chlorine, including plasma dry etching, or wet etching, such as with dilute HF or HCl. Additionally, organic materials may be ashed in one or more processing operations, exposing the materials to oxygen, nitrogen, and/or hydrogen plasma effluents. Silicon-and-carbon-containing materials according to embodiments of the present technology may be substantially maintained during any of these operations, such as greater than or about 50% of the material illustrated in FIG. 3C. Silicon-and-carbon-containing materials may provide improved survivability compared to conventional films, while also maintaining relatively low dielectric constant and improved electrical performance.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor and a carbon-containing precursor to a processing region of a semiconductor processing chamber, wherein the carbon-containing precursor is characterized by a carbon-carbon double bond or a carbon-carbon triple bond, and wherein a substrate is disposed within the processing region of the semiconductor processing chamber;
providing an oxygen-containing precursor to the processing region of the semiconductor processing chamber;
thermally reacting the silicon-containing precursor, the carbon-containing precursor, and the oxygen-containing precursor at a temperature less than or about 700° C.; and
forming a silicon-and-carbon-containing layer on the substrate.

2. The semiconductor processing method of claim 1, wherein:
the oxygen-containing precursor comprises nitrous oxide.

3. The semiconductor processing method of claim 1, wherein:
thermally reacting the silicon-containing precursor, the carbon-containing precursor, and the oxygen-containing precursor is performed at a temperature less than or about 575° C.

4. The semiconductor processing method of claim 1, wherein:
a pressure within the semiconductor processing chamber is maintained at greater than or about 3 Torr while forming the silicon-and-carbon-containing layer.

5. The semiconductor processing method of claim 1, wherein:
the processing region of the semiconductor processing chamber is maintained plasma-free while forming the silicon-and-carbon-containing layer on the substrate.

6. The semiconductor processing method of claim 1, wherein:
the carbon-containing precursor is provided at a flow rate ratio to the silicon-containing precursor of greater than or about 4:1.

7. The semiconductor processing method of claim 1, wherein:
the substrate is characterized by one or more features, and wherein the silicon-and-carbon-containing layer is formed about the one or more features with a conformality of greater than or about 80%.

8. The semiconductor processing method of claim 1, wherein:
the silicon-and-carbon-containing layer is characterized by a carbon concentration of less than or about 30 at. %.

9. The semiconductor processing method of claim 1, further comprising:
cycling delivery of the oxygen-containing precursor while maintaining delivery of the silicon-containing precursor and the carbon-containing precursor.

10. The semiconductor processing method of claim 9, wherein:
periods of time of providing the oxygen-containing precursor are between about 0.5 s and about 10 s.

11. The semiconductor processing method of claim 1, wherein:
the silicon-and-carbon-containing layer is formed at least partially around one or more alternating stacks of silicon and silicon germanium.

12. A semiconductor processing method comprising:
providing a silicon-containing precursor and a carbon-containing precursor to a processing region of a semiconductor processing chamber, wherein the carbon-containing precursor is provided at a flow rate ratio to the silicon-containing precursor of greater than or about 4:1, and wherein a substrate is disposed within the processing region of the semiconductor processing chamber;
providing an oxygen-containing precursor to the processing region of the semiconductor processing chamber;
thermally reacting the silicon-containing precursor, the carbon-containing precursor, and the oxygen-containing precursor at a temperature less than or about 650° C.; and
forming a silicon-and-carbon-containing layer on the substrate.

13. The semiconductor processing method of claim 12, wherein:
the oxygen-containing precursor comprises nitrous oxide.

14. The semiconductor processing method of claim 12, wherein:
the processing region of the semiconductor processing chamber is maintained plasma-free during the semiconductor processing method.

15. The semiconductor processing method of claim 12, further comprising:
cycling delivery of the oxygen-containing precursor while maintaining delivery of the silicon-containing precursor and the carbon-containing precursor, wherein periods of time of providing the oxygen-containing precursor are between about 0.5 s and about 10 s.

16. A semiconductor processing method comprising:
providing a silicon-containing precursor and a carbon-containing precursor to a processing region of a semiconductor processing chamber, wherein the silicon-containing precursor comprises disilane, wherein the carbon-containing precursor is characterized by a carbon-carbon double bond or a carbon-carbon triple bond, and wherein a substrate is disposed within the processing region of the semiconductor processing chamber, and wherein one or more alternating stacks of silicon and silicon germanium is disposed on the substrate;
providing an oxygen-containing precursor to the processing region of the semiconductor processing chamber, wherein the oxygen-containing precursor comprises nitrous oxide, and wherein the oxygen-containing precursor is provided discontinuously;
thermally reacting the silicon-containing precursor, the carbon-containing precursor, and the oxygen-containing precursor at a temperature less than or about 600° C.; and
forming a silicon-and-carbon-containing layer on the substrate, wherein the silicon-and-carbon-containing layer is formed at least partially around the one or more alternating stacks of silicon and silicon germanium.

17. The semiconductor processing method of claim 16, wherein:
the processing region of the semiconductor processing chamber is maintained plasma-free during the semiconductor processing method.

18. The semiconductor processing method of claim 16, wherein:
the silicon-and-carbon-containing layer is formed about the one or more features with a conformality of greater than or about 85%.

19. The semiconductor processing method of claim 16, wherein:
the silicon-and-carbon-containing layer is characterized by a carbon concentration of less than or about 30 at. %.

20. The semiconductor processing method of claim 16, further comprising:
exposing the silicon-and-carbon-containing layer to an oxygen-containing plasma, a hydrogen-containing plasma, or a wet etch process, wherein the silicon-and-carbon-containing layer is maintained at least 50% of the thickness.
